(19) United States
(12) Patent Application Publication
(10) Pub. No.: US 2023/0047654 A1
(43) Pub. Date: Feb. 16, 2023

(54) WIRING MODULE

(71) Applicants: AUTONETWORKS TECHNOLOGIES, LTD., Mie (JP); SUMITOMO WIRING SYSTEMS, LTD., Mie (JP); SUMITOMO ELECTRIC INDUSTRIES, LTD., Osaka (JP)

(72) Inventors: Shinichi TAKASE, Osaka (JP); Xueqing DONG, Osaka (JP); Hiroomi HIRAMITSU, Osaka (JP); Yuto SATO, Osaka (JP)

(73) Assignees: AUTONETWORKS TECHNOLOGIES, LTD., Mie (JP); SUMITOMO WIRING SYSTEMS, LTD., Mie (JP); SUMITOMO ELECTRIC INDUSTRIES, LTD., Osaka (JP)

(21) Appl. No.: 17/767,699

(22) PCT Filed: Sep. 1, 2020
(86) PCT No.: PCT/JP2020/033042

§ 371 Date: Apr. 8, 2022

(30) Foreign Application Priority Data
Oct. 17, 2019 (JP) 2019-189919
Jun. 12, 2020 (JP) 2020-102114

(51) Int. Cl. H01M 50/507; H01M 50/204; H01M 50/519; H05K 1/18; H01R 12/77; B60R 16/02; H01M 10/42

(52) U.S. Cl. CPC H01M 50/507; H01M 50/204; H01M 50/519; H05K 1/189; H01R 12/77; B60R 16/0207; H01M 10/425

(57) ABSTRACT

A wiring module includes a first flexible printed circuit and a second flexible printed circuit that is separate from the first flexible printed circuit. The first flexible printed circuit and the second flexible printed circuit are arranged so as to be continuous in a first direction and are shaped as a band that extends in the first direction. A connector is mounted to each of the first flexible printed circuit and the second flexible printed circuit. The fitting direction in which the connector mounted to the first flexible printed circuit is fitted to a partner connector is different from the fitting direction in which the connector mounted to the second flexible printed circuit is fitted to a partner connector.

### TECHNICAL FIELD

The present specification discloses technology relating to a wiring module.

### BACKGROUND ART

Wiring modules mounted in vehicles such as electric automobiles and hybrid vehicles are conventionally known. A wiring module in JP 2013-45508A (Patent Document 1) includes a flexible printed circuit in which multiple conductive paths are formed. A connector portion is provided at an end portion of the flexible printed circuit to enable information regarding states of the vehicle to be transmitted to the outside.

### CITATION LIST

### Patent Documents

Patent Document 1: JP 2013-45508A

### SUMMARY OF INVENTION

### Technical Problem

In the configuration in Patent Document 1, if the number of electrical wires increases due to an increase in the vehicular wire harness voltage, the connector portion requires a larger number of poles and a larger size. Therefore, it becomes difficult to reduce the height of the wiring module.

### Solution to Problem

A wiring module disclosed in the present specification includes: a first flexible printed circuit; and a second flexible printed circuit provided separately from the first flexible printed circuit, wherein the first flexible printed circuit and the second flexible printed circuit are arranged so as to be continuous in a first direction and are shaped as a band that extends in the first direction, a connector is mounted to each of the first flexible printed circuit and the second flexible printed circuit, and a fitting direction in which the connector mounted to the first flexible printed circuit is fitted to a partner connector is different from a fitting direction in which the connector mounted to the second flexible printed circuit is fitted to a partner connector.

### Advantageous Effects of Invention

According to the technology described in the present specification, it is possible to provide a wiring module that can have a reduced height.

### BRIEF DESCRIPTION OF DRAWINGS

FIG. 1 is a perspective view of a power storage module according to a first embodiment.

FIG. 2 is a perspective view of a wiring module.

FIG. 3 is a plan view of the wiring module.

FIG. 4 is a cross-sectional view taken along a line A-A in FIG. 3.

FIG. 5 is a cross-sectional view taken along a line B-B in FIG. 3.

FIG. 6 is a cross-sectional view taken along a line C-C in FIG. 3.

FIG. 7 is a cross-sectional view taken along a line D-D in FIG. 3.

FIG. 8 is a perspective view illustrating a process of attaching a first FPC and a second FPC to a protector.

FIG. 9 is a perspective view of a state in which the first FPC and the second FPC have been attached to the protector.

FIG. 10 is a schematic diagram of a vehicle in which the power storage module is mounted.

FIG. 11 is a plan view of a power storage module according to a second embodiment.

### DESCRIPTION OF EMBODIMENTS

### Description of Embodiments of Present Disclosure

First, embodiments of the present disclosure will be listed and described.

(1) A wiring module according to an aspect of the present disclosure includes: a first flexible printed circuit; and a second flexible printed circuit provided separately from the first flexible printed circuit, wherein the first flexible printed circuit and the second flexible printed circuit are arranged so as to be continuous in a first direction and are shaped as a band that extends in the first direction, a connector is mounted to each of the first flexible printed circuit and the second flexible printed circuit, and a fitting direction in which the connector mounted to the first flexible printed circuit is fitted to a partner connector is different from a fitting direction in which the connector mounted to the second flexible printed circuit is fitted to a partner connector.

According to the above configuration, a connector is mounted to each of the first flexible printed circuit and the second flexible printed circuit such that two connectors are provided in the wiring module overall, and thus the dimensions (e.g., height or width) of the connectors can be smaller than in a configuration in which one connector is provided in one flexible printed circuit. This makes it possible to reduce the height of the wiring module.

(2) The connector mounted to the first flexible printed circuit may be mounted to an end portion of the first flexible printed circuit on a side opposite to the second flexible printed circuit.

According to this configuration, the connector mounted to the first flexible printed circuit and the partner connector can be easily fitted together.

(3) The connector mounted to the second flexible printed circuit may be mounted to an end portion of the second flexible printed circuit on a side opposite to the first flexible printed circuit.

According to this configuration, the connector mounted to the second flexible printed circuit and the partner connector can be easily fitted together.

(4) The connectors may be arranged inward of the first flexible printed circuit and the second flexible printed circuit in the first direction.

According to this configuration, the size of the wiring module can be reduced in the first direction.

(5) The connectors may be arranged inward of the first flexible printed circuit and the second flexible printed circuit in a second direction that is orthogonal to the first direction.

According to this configuration, the size of the wiring module can be reduced in the second direction.

(6) The connectors may be open in the first direction.

According to this configuration, the connector and the partner connector can be fitted to each other in the first direction.

(7) At least one of the first flexible printed circuit and the second flexible printed circuit may include a first extension portion that extends in a band shape and a second extension portion that extends in band shape along the first extension portion while being separated from the first extension portion by a gap.

According to this configuration, the height of the wiring module can be reduced even in the case of a configuration in which a flexible printed circuit cannot be arranged in the region between the first extension portion and the second extension portion.

(8) The wiring module may further include an insulating protector having a first region on which the first flexible printed circuit is arranged and a second region on which the second flexible printed circuit is arranged, wherein the first flexible printed circuit and the second flexible printed circuit may each include a fixing portion that is fixed to the protector.

According to this configuration, the first flexible printed circuit and the second flexible printed circuit can be fixed to the protector to obtain an integrated body, thus making transportation, attachment, and the like easier to perform.

(9) The first flexible printed circuit and the second flexible printed circuit may each include a mounting surface on which the connector is mounted, and the protector may include a mounting recessed portion that is recessed in a direction opposite to the connectors in a region corresponding to the mounting surface of at least one of the first flexible printed circuit and the second flexible printed circuit.

According to this configuration, it is possible to reduce the height dimension of the wiring module at the portion where at least one of the connectors is mounted.

(10) The protector may include a mounting recessed portion that is recessed in a direction opposite to the connectors in regions corresponding to the mounting surfaces of both the first flexible printed circuit and the second flexible printed circuit.

According to this configuration, it is possible to further reduce the height dimension of the wiring module at the portions where the connectors are mounted.

(11) The wiring module may be a vehicular wiring module that is to be mounted and used in a vehicle.

According to this configuration, it is possible to reduce the height of the wiring module and reduce the amount of space occupied by a power storage pack or the like in the vehicle.

### Details of Embodiments of Present Disclosure

Specific examples of the present disclosure will be described below with reference to the drawings. Note that the present disclosure is not limited to these examples, but rather is indicated by the scope of claims, and is intended to include all modifications within the meaning and scope equivalent to the claims.

### First Embodiment

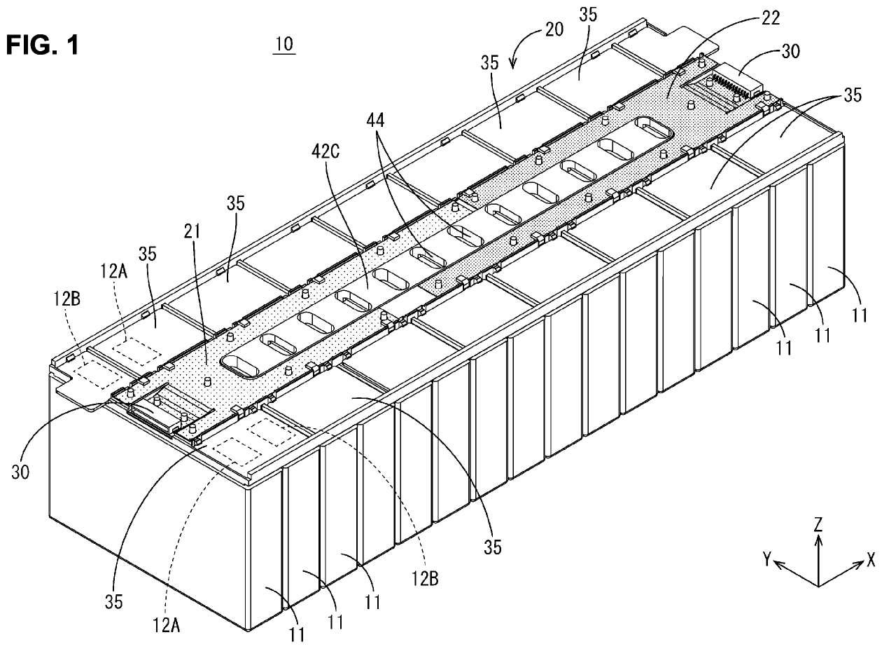

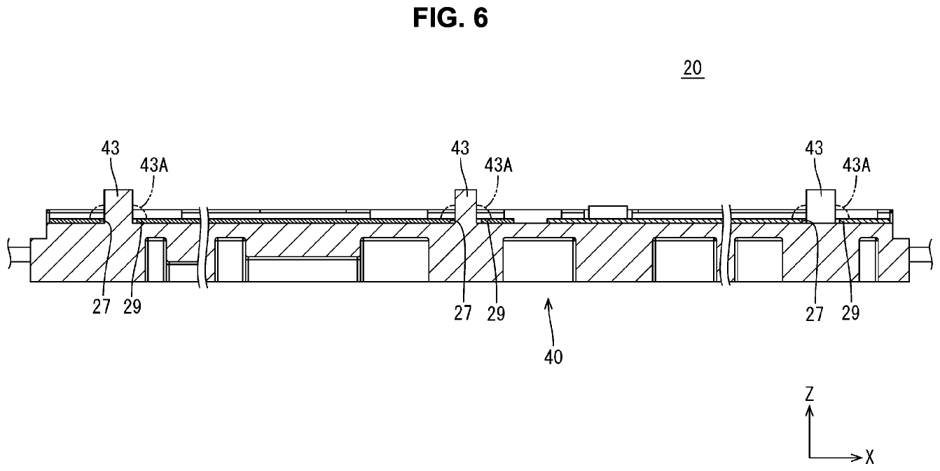

The following describes a first embodiment with reference to FIGS. 1 to 10.

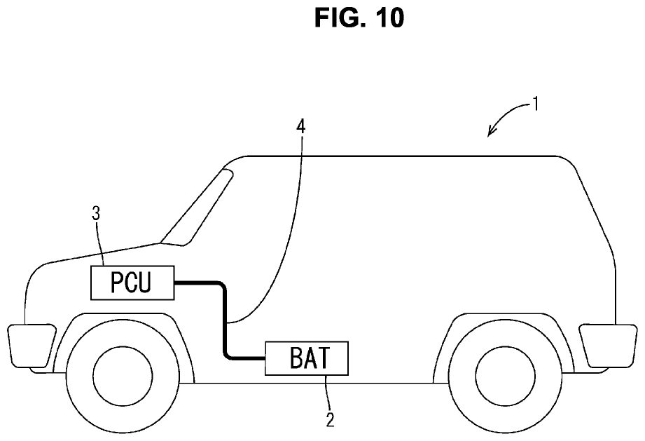

A power storage module 10 of the present embodiment is for application to a power storage pack 2 that is to be mounted in a vehicle 1 as shown in FIG. 10, for example. The power storage pack 2 is to be mounted in the vehicle 1, which is an electric automobile, a hybrid automobile, or the like, and is for use as a drive source for the vehicle 1. In the following description, when there are a plurality of members that are the same, only some of the members may be designated with reference numerals, and the reference numerals of other members may be omitted.

### Overall Configuration

As shown in FIG. 10, the power storage pack 2 is arranged near the center of the vehicle 1. A PCU 3 (Power Control Unit) is arranged in a front portion of the vehicle 1. The power storage pack 2 and the PCU 3 are connected by a wire harness 4. The power storage pack 2 and the wire harness 4 are connected by a connector (not shown). The power storage pack 2 includes a power storage module 10 that includes a plurality of power storage elements 11. The power storage module 10 (and the wiring module 20) can be mounted in any orientation, but in the following description, with respect to FIG. 1, the X direction is the forward direction, the Y direction is the leftward direction, and the Z direction is the upward direction. Note that the forward-rearward direction is an example of a first direction, and the left-right direction is an example of a second direction.

### Power Storage Module 10

As shown in FIG. 1, the power storage module 10 includes a plurality of power storage elements 11 arranged in a row and a wiring module 20 mounted on the upper surfaces of the power storage elements 11. Each of the power storage elements 11 is shaped as a flattened rectangular parallelepiped and houses a power storage element (not shown) therein, and also has positive and negative electrode terminals 12A and 12B on the upper surface.

### Wiring Module 20

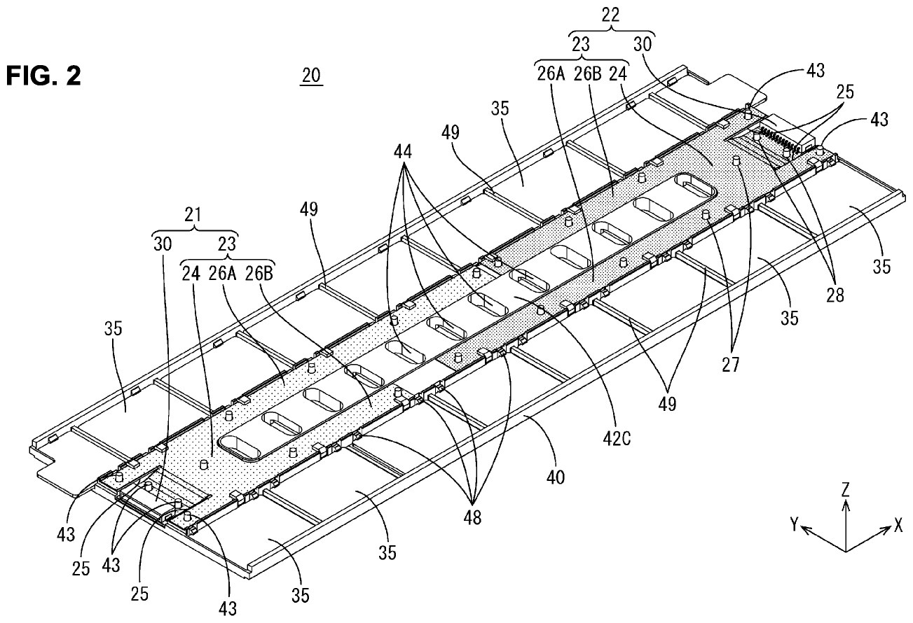

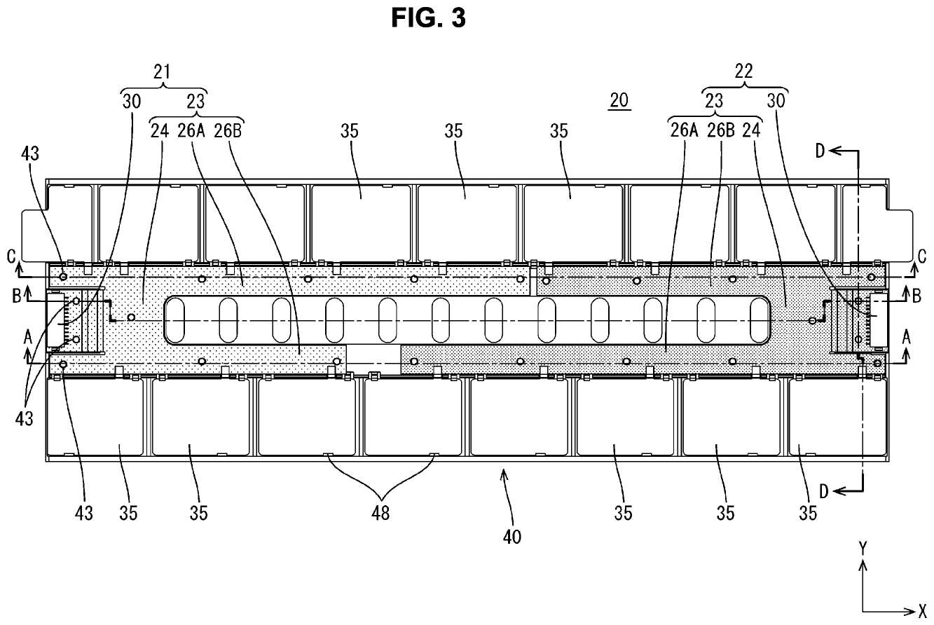

As shown in FIGS. 2 and 3, the wiring module 20 includes a first flexible printed circuit (hereinafter referred to as “first FPC 21”), a second flexible printed circuit (hereinafter referred to as “second FPC 22”), a plurality of bus bars 35, and a protector 40 that holds the first FPC 21, the second FPC 22, and the bus bars 35.

### First FPC 21 and Second FPC 22

The first FPC 21 and the second FPC 22 both include a flexible and deformable FPC body 23 and a connector 30 mounted to one terminal portion of the FPC body 23. The FPC body 23 includes a base film made of an insulating synthetic resin, conductive paths formed in the base film, and an insulating layer that is made of an insulating overlay film or a coating film and covers the base film. The first FPC 21 and the second FPC 22 can be formed by printing, etching, plating, or the like.

The materials forming the base film and the insulating layer can be selected from among various synthetic resins as needed, such as a thermosetting resin (e.g., epoxy resin), a thermoplastic resin, or a liquid crystal polymer (LCP). The thermoplastic resin can be any thermoplastic resin as needed, such as polypropylene (PP), polyethylene (PE), polyphenylene sulfide (PPS), polyethylene terephthalate (PET), polybutylene terephthalate (PBT), or polyimide (PI). The conductive path is constituted by a metal foil made of copper, a copper alloy, aluminum, an aluminum alloy, or the like, and electronic components are mounted on the conductive path. Examples of the electronic components include an FET (Field Effect Transistor), a resistor, a capacitor, a coil, and a thermistor.

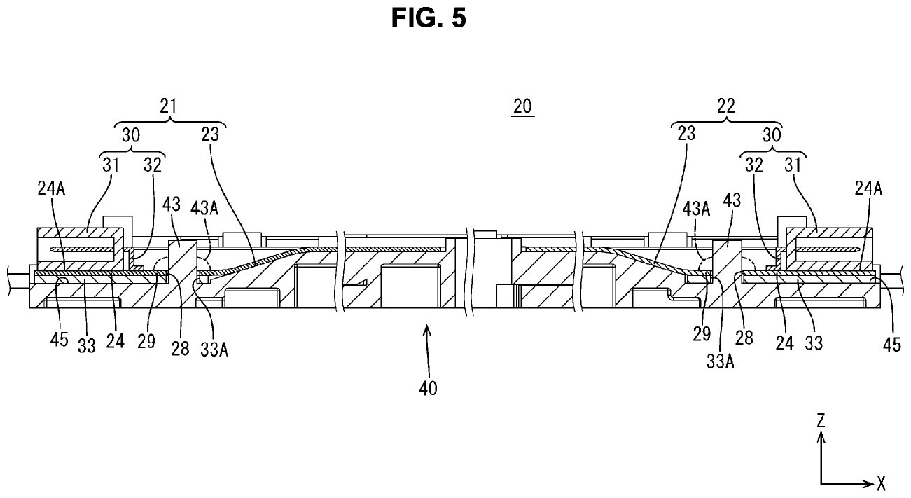

The FPC bodies 23 of the first FPC 21 and the second FPC 22 each include a base portion 24 having a region for mounting the connector 30, and a pair of extension portions 26A and 26B that extend in a band shape in the forward-rearward direction from the base portion 24. Each base portion 24 includes a pair of slit portions 25 formed on respective sides of the connector 30. The connector 30 is mounted on a mounting surface 24A (FIG. 5) formed between the pair of slit portions 25. As shown in FIG. 2, the pair of extension portions 26A and 26B are a first extension portion 26A and a second extension portion 26B that have different lengths in the forward-rearward direction (extension direction), both have a smaller width than the base portion 24, and extend parallel to each other across a gap. A gap that exposes the protector 40 is provided between the pair of extension portions 26A and 26B of the first FPC 21 and the pair of extension portions 26A and 26B of the second FPC 22.

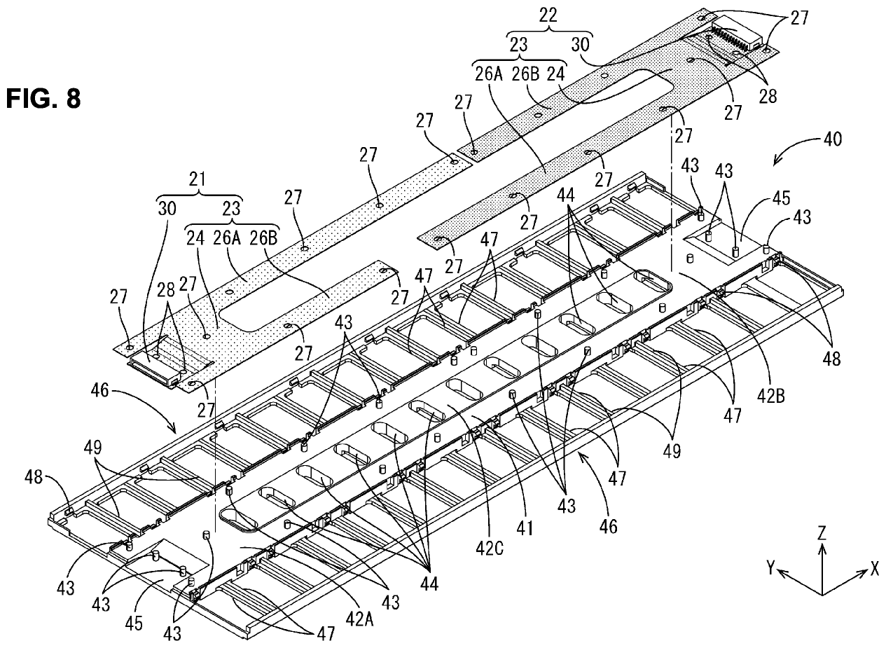

As shown in FIG. 8, a plurality of first through-holes 27 and a plurality of second through-holes 28 are formed in the FPC body 23 of both the first FPC 21 and the second FPC 22. The first through-holes 27 have an elliptical shape and are elongated in the forward-rearward direction, and are provided side by side at predetermined intervals in the forward-rearward direction so as to pass through the pair of extension portions 26A and 26B of each FPC body 23. Also, one first through-hole 27 is provided in the central portion of each base portion 24. The hole diameter of the first through-holes 27 in the major axis direction (forward-rearward direction) is set appropriately according to tolerance with respect to later-described protruding portions 43 of the protector 40, which depends on the length in the extension direction (forward-rearward direction) of each FPC body 23.

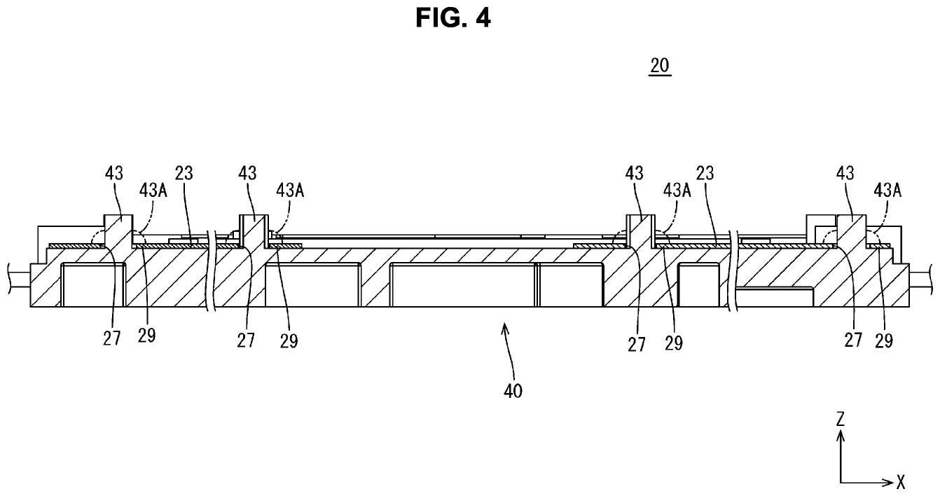

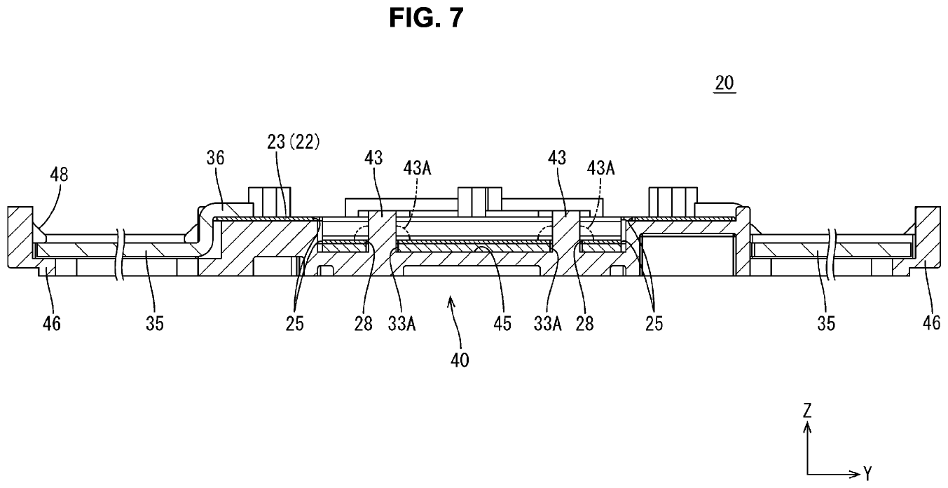

As shown in FIGS. 5 and 7, the two second through-holes 28 have a perfect circular shape and a smaller diameter than the first through-holes 27 in the forward-rearward direction, and are provided in the vicinity of the corresponding connector 30. Specifically, the pair of second through-holes 28 are arranged side by side on the back surface side of the connector 30 at locations inward of the slit portions 25 on opposite sides of the connector 30. As shown in FIGS. 4 and 5, regions surrounding the first through-holes 27 and the second through-holes 28 (hole edge portions) in the FPC body 23 are fixing portions 29 that are fixed to the protector 40. As shown in FIG. 5, reinforcing plates 33 are arranged under the front and rear end portions of each FPC body 23. Each reinforcing plate 33 is provided with a passage hole 33A that is in communication with the corresponding second through-hole 28, and is fixed to the corresponding FPC body 23 using an adhesive or the like.

### Connector 30

Each of the connectors 30 includes a housing 31 that is made of a synthetic resin and connector terminals 32 that are held in the housing 31. The connector terminals 32 are soldered to lands that are connected to the conductive path of the FPC body 23. The connector 30 is connected to a partner connector connected to the terminal portions of electrical wires. The partner connector is connected to an external ECU (Electronic Control Unit) or the like via an electrical wire. The voltage of the bus bar 35 is output to the ECU via the conductive path of the FPC body 23. The ECU has a well-known configuration provided with a microcomputer, elements, and the like, and has functions for detecting the voltage, current, temperature, and the like of the power storage elements 11 and controlling the charging and discharging of the power storage elements 11.

As shown in FIG. 5, the connector 30 provided on the first FPC 21 is open rearward and is mounted to the rear end portion of the first FPC 21, and thus the partner connector is arranged facing forward when being inserted and fitted into the connector 30. On the other hand, the connector 30 provided on the second FPC 22 is open forward and is mounted to the front end portion of the second FPC 22, and thus the partner connector is arranged facing rearward when being inserted and fitted into the connector 30. In other words, the partner connectors can be fitted from the front and the rear to the connectors 30 arranged at the front end portion and the rear end portion of the wiring module 20 (and the power storage module 10). Also, as shown in FIG. 3, the connectors 30 are arranged inward of the outer edges of the first FPC 21 and the second FPC 22, thus making it possible to reduce the dimensions of the wiring module 20 in the forward-rearward direction and the left-right direction.

Because a connector 30 is mounted to each of the first and second FPCs 21 and 22, two connectors 30 are provided in the wiring module 20 overall. For this reason, compared to a wiring module in which one connector is mounted on one FPC, the number of connector terminals (number of poles) per connector can be reduced, and the dimensions of the connector can be reduced. For example, in FIG. 5 of the present embodiment, the connectors 30 are a so-called single-level type of connector in which the tips of the connector terminals 32 are arranged at the same height inside the housing 31, thus leading to a lower profile in the height direction of the wiring module 20. On the other hand, if there is only one connector, it is conceivable that due to the connector terminals being concentrated for each pole, the connector is a two-level type of connector, and the height dimension of the connector (and wiring module) is doubled.

### Bus Bar 35

The bus bars 35 are each rectangular and constituted by a metal plate member made of copper, a copper alloy, aluminum, an aluminum alloy, or the like, and each connect adjacent electrode terminals 12A and 12B. A peripheral edge portion of each of the bus bars 35 is provided with a connection piece 36 that can be connected to a land that is connected to the conductive path of the first FPC 21 or the second FPC 22. The connection pieces 36 and the lands are connected by soldering or the like.

### Protector 40

The protector 40 is made of an insulating synthetic resin, and as shown in FIG. 8, includes a plate-shaped protector body 41 and bus bar arrangement portions 46 that are connected to opposite sides of the protector body 41 and are for placement of the bus bars 35. Amounting recessed portion 45 having a recessed upper surface is formed at both the front and rear end portions of the protector body 41. The end portions of the wiring module 20 are lowered in height by mounting the connectors 30 in the mounting recessed portions 45.

The protector body 41 has a first region 42A on which the first FPC 21 is placed, a second region 42B on which the second FPC 22 is placed, and a ventilation region 42C surrounded by the first region 42A and the second region 42B. The ventilation region 42C is a region that extends in a band shape in the forward-rearward direction, and includes a plurality of ventilation holes 44 that pass through the protector body 41 and are provided side by side in the forward-rearward direction. The ventilation holes 44 allow gas generated by the power storage elements 11 to escape to the outside, for example.

Protruding portions 43 for positioning the first FPC 21 and the second FPC 22 are provided so as to rise from the plate surface in the first region 42A and the second region 42B. The protruding portions 43 each have a columnar shape capable of being inserted into a corresponding first through-hole 27 or second through-hole 28, and are provided at positions corresponding to the first through-holes 27 and the second through-holes 28. Specifically, the protruding portions 43 are provided side by side at intervals in the forward-rearward direction in the vicinity of the peripheral edges of the protector body 41, and are also formed in the mounting recessed portions 45 and in the vicinity of the mounting recessed portions 45. The protruding portions 43 fix the first FPC 21 and the second FPC 22 to the protector 40 by deforming in heat welding, for example. The height (dimension in the axial direction) of the protruding portions 43 is set such that the protruding portions 43 pass through the through-holes 27 and 28 and project upward from the through-holes 27 and 28 when the first FPC 21 and the second FPC 22 are placed at predetermined locations on the protector 40 before welding. On the other hand, when the protruding portions 43 are melted by heat welding and then solidify, as shown in FIGS. 4 and 5, rivet-shaped locking portions 43A having a larger diameter than the first through-holes 27 and the second through-holes 28 are formed on the FPC body 23.

Each bus bar arrangement portion 46 holds a plurality of bus bars 35 arranged side by side in the forward-rearward direction, and as shown in FIG. 8, is provided with passage holes 47 for passage of the electrode terminals 12A and 12B of the power storage elements 11, restricting claws 48 that restrict detachment of the bus bars 35, and insulating walls 49 for insulation from adjacent bus bars 35 in the row direction.

The following describes the assembly of the wiring module 20.

As shown in FIG. 8, four (a plurality of) protruding portions 43 at the front and rear end portions of the protector 40 are inserted into two (a plurality of) corresponding first through-holes 27 and two (a plurality of) corresponding second through-holes 28 of the first FPC 21 and the second FPC 22. Here, the clearance between the second through-holes 28 and the corresponding protruding portions 43 is small, and therefore the end portions on one side (the end portions on the connector 30 side) of the first FPC 21 and the second FPC 22 are positioned based on the positions of the second through-holes 28. Then, with respect to the FPC body 23, the protruding portions 43 are inserted into the corresponding first through-holes 27 in order beginning from the side near the connector 30. At this time, there is tolerance between the positions of the protruding portions 43 and the positions of the first through-holes 27 depending on the length of the first FPC 21, but when compared with the overall length of the protector 40 in the forward-rearward direction, the length of either the first FPC 21 or the second FPC 22 is shorter. Accordingly, the tolerance between the protruding portions 43 and the first through-holes 27 is small enough to not hinder the insertion of the protruding portions 43 into all of the corresponding first through-holes 27. In other words, in the present embodiment, the first FPC 21 and the second FPC 22 are arranged so as to be continuous in the forward-rearward direction and are shaped as a band that extends in the forward-rearward direction, thus making it possible to absorb tolerance with the protector 40 in the extending direction (forward-rearward direction) of the first FPC 21 and the second FPC 22 in which the tolerance can easily arise between the protector 40 and the first and second FPCs 21 and 22.

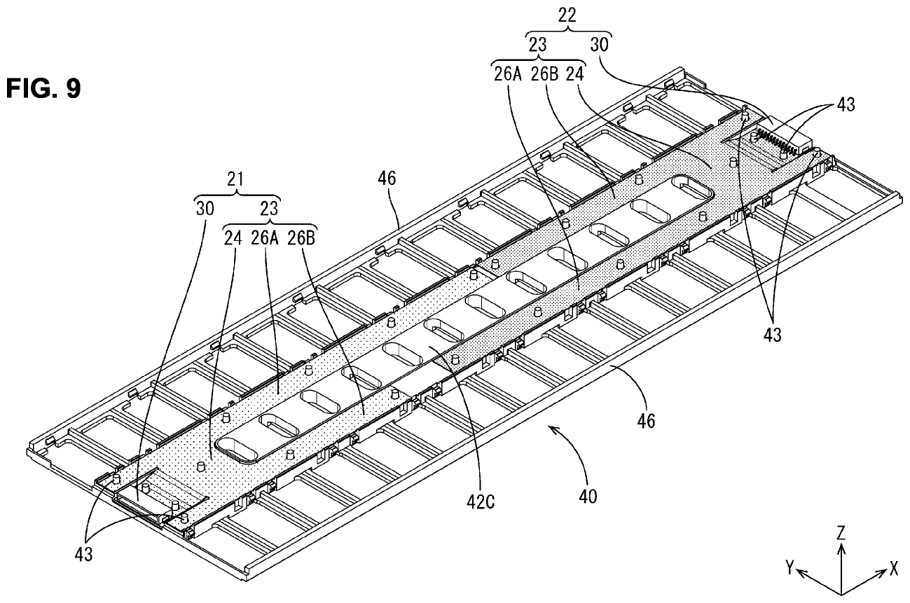

Similarly, for the other one out of the first FPC 21 and the second FPC 22, four (a plurality of) protruding portions 43 near the end portion of the protector 40 are inserted into the corresponding first through-holes 27 and second through-holes 28 of the second FPC 22 such that positioning is performed using the second through-holes 28 and the corresponding protruding portions 43, and then the protruding portions 43 are inserted into the corresponding first through-holes 27 in order beginning from the first through-hole 27 closest to the connector 30 (FIG. 9).

Then, after the first FPC 21 and the second FPC 22 are mounted at predetermined positions on the protector 40, a tool or the like is used to heat weld the protruding portions 43 that pass through the first through-holes 27 and the second through-holes 28 (see FIGS. 4 and 5). As a result, the tips of the protruding portions 43 are melted to form the locking portions 43A, and the FPC body 23 is fixed to the protector 40. Next, the bus bars 35 are arranged side by side on the bus bar arrangement portions 46, and the connection pieces 36 are soldered to the lands of the FPC bodies 23. The wiring module 20 is thus formed (FIG. 2).

Next, the wiring module 20 is arranged on the power storage elements 11, and the bus bars 35 are connected to adjacent electrode terminals 12A and 12B by welding or the like, and thus the power storage module 10 is formed (FIG. 1).

Actions and effects described below are exhibited by the present embodiment.

A wiring module 20 includes: a first FPC 21; and a second FPC 22 that is separate from the first FPC 21, wherein the first FPC 21 and the second FPC 22 are arranged so as to be continuous in a forward-rearward direction and are shaped as a band that extends in the forward-rearward direction, a connector 30 is mounted to each of the first FPC 21 and the second FPC 22, and a fitting direction in which the connector 30 mounted to the first FPC 21 is fitted to a partner connector is different from a fitting direction in which the connector 30 mounted to the second FPC 22 is fitted to a partner connector.

According to the present embodiment, a connector 30 is mounted to each of the first FPC 21 and the second FPC 22 such that two connectors 30 are provided in the wiring module 20 overall, and thus the dimensions (e.g., height or width) of the connectors 30 can be smaller than in a configuration in which one connector is provided. This makes it possible to reduce the height of the wiring module 20.

Also, the connector 30 mounted to the first FPC 21 is mounted to an end portion of the first FPC 21 on the side opposite to the second FPC 22.

According to this configuration, the connector 30 mounted to the first FPC 21 and the partner connector can be easily fitted together.

Also, the connector 30 mounted to the second FPC 22 is mounted to an end portion of the second FPC 22 on the side opposite to the first FPC 21.

According to this configuration, the connector 30 mounted to the second FPC 22 and the partner connector can be easily fitted together.

Also, the connectors 30 are arranged inward of the first FPC 21 and the second FPC 22 in the forward-rearward direction.

According to this configuration, the size of the wiring module 20 can be reduced in the forward-rearward direction.

Also, the connectors 30 are arranged inward of the first FPC 21 and the second FPC 22 in a left-right direction.

According to this configuration, the size of the wiring module 20 can be reduced in the left-right direction.

Also, the connectors 30 are open in the forward-rearward direction.

According to this configuration, the connectors 30 and the partner connectors can be fitted to each other in the forward-rearward direction.

Also, at least either the first FPC 21 or the second FPC 22 includes a first extension portion 26A that extends in a band shape and a second extension portion 26B that extends in band shape along the first extension portion 26A while being separated from the first extension portion 26A by a gap.

According to this configuration, the height of the wiring module 20 can be reduced even in the case of a configuration in which a FPC cannot be arranged in the region between the first extension portion 26A and the second extension portion 26B.

The wiring module further includes: an insulating protector 40 having a first region 42A on which the first FPC 21 is arranged and a second region 42B on which the second FPC 22 is arranged, wherein the first FPC 21 and the second FPC 22 each include a fixing portion 29 that is fixed to the protector 40.

According to this configuration, the first FPC 21 and the second FPC 22 can be fixed to the protector 40 to obtain an integrated body, thus making transportation, attachment, and the like easier to perform.

Also, the first FPC 21 and the second FPC 22 each include a mounting surface 24A on which the connector 30 is mounted, and the protector 40 includes a mounting recessed portion 45 that is recessed in a direction opposite to the connectors 30 in a region corresponding to the mounting surface 24A of at least either the first FPC 21 or the second FPC 22.

According to this configuration, it is possible to reduce the height dimension of the wiring module 20 at the portion where at least one of the connectors 30 is mounted.

Also, the protector 40 includes a mounting recessed portion 45 that is recessed in a direction opposite to the connectors 30 in regions corresponding to the mounting surfaces 24A of both the first FPC 21 and the second FPC 22.

According to this configuration, it is possible to further reduce the height dimension of the wiring module 20 at the portions where the connectors 30 are mounted.

Also, the wiring module 20 is a vehicular wiring module 20 that is to be mounted and used in a vehicle 1.

According to this configuration, it is possible to reduce the height of the wiring module 20 and reduce the amount of space occupied by the power storage pack 2 and the like in the vehicle 1.

### Second Embodiment

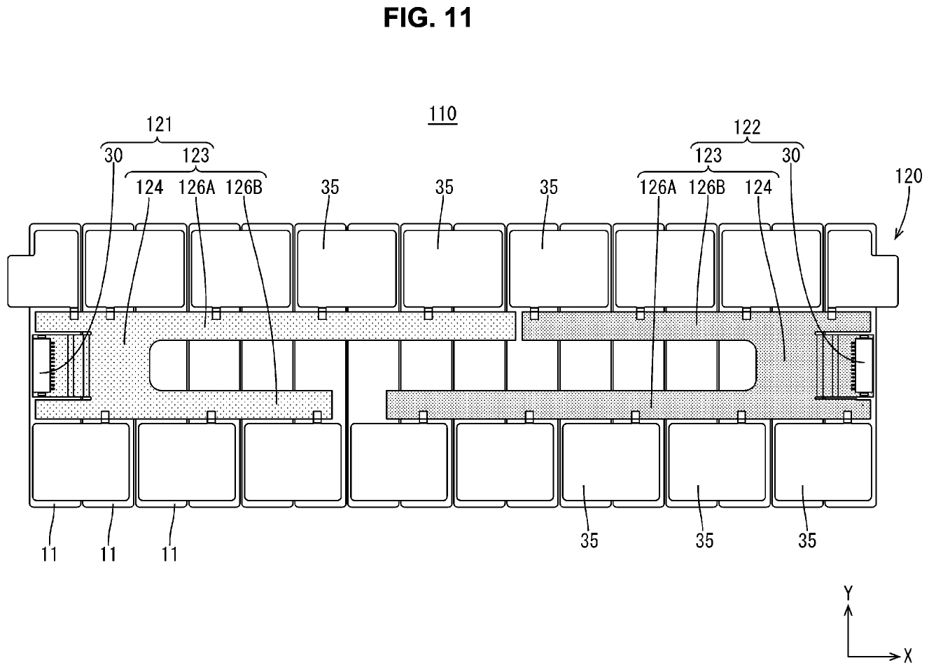

The following describes a second embodiment with reference to FIG. 11. Descriptions will not be given for members, actions, and effects that are the same as in the first embodiment.

The power storage module 110 of the present embodiment is configured by mounting a wiring module 120 on a plurality of power storage elements 11. The power storage module 110 (and the wiring module 120) can be mounted in any orientation, but in the following description, with respect to FIG. 11, the X direction is the forward direction, and the Y direction is the leftward direction. Note that the forward-rearward direction is an example of a first direction, and the left-right direction is an example of a second direction.

### Power Storage Module 110

As shown in FIG. 11, the power storage module 110 includes a plurality of power storage elements 11 arranged in a row and a wiring module 120 mounted on the upper surfaces of the power storage elements 11.

### Wiring Module 120

As shown in FIG. 11, the wiring module 120 includes a first FPC 121, a second FPC 122, and a plurality of bus bars 35. Unlike the wiring module 20 of the first embodiment, the wiring module 120 does not include a protector, but has actions and effects similar to those of the first embodiment.

### First FPC 21 and Second FPC 122

The first FPC 121 and the second FPC 122 both include a flexible and deformable FPC body 123 and a connector 30 mounted to one terminal portion of the FPC body 123.

The FPC bodies 123 of the first FPC 121 and the second FPC 122 each include a base portion 124 having a region for mounting the connector 30, and a pair of extension portions 126A and 126B that extend in a band shape in the forward-rearward direction from the base portion 124. The connector 30 is open on the side of the base portion 124 opposite to the pair of extension portions 126A and 126B, and is fitted to a partner connector in the forward-rearward direction.

The following describes the assembly of the wiring module 120.

Bus bars 35 are soldered to lands of the FPC bodies 123. As a result, the wiring module 120 is formed.

Next, the wiring module 120 is placed on the power storage elements 11 such that the connectors 30 are arranged at the front end portion and the rear end portion of the power storage module 110. The bus bars 35 are then connected to adjacent electrode terminals by welding or the like, thus forming the power storage module 110.

Note that besides the above-described method of assembling the wiring module 120, it is also possible to apply a method in which the bus bars 35 are connected to the power storage elements 11, then the first FPC 121 and the second FPC 122 are arranged on the power storage elements 11, and then the bus bars 35 are connected the FPC bodies 123.

### Other Embodiments

The technology described in the present specification is not limited to the embodiments described above and in the drawings, and for example, embodiments such as the following are also included in the technical scope of the technology described herein.

(1) Although the connector 30 is arranged inward of the first FPC 21, 121 or the second FPC 22, 122 in the forward-rearward direction and the left-right direction, the connector may project outward of the first FPC 21, 121 or the second FPC 22, 122 in the forward-rearward direction and the left-right direction.

(2) Although the wiring module 20, 120 includes the bus bars 35, it may be a wiring module that does not include bus bars.

(3) The shapes of the first through-holes 27 and the second through-holes 28 are not limited to the shapes described in the above embodiments. For example, the first through-holes may be shaped as perfect circle having a size (diameter) capable of absorbing tolerance.

(4) Although the protruding portions 43 are inserted into the first through-holes 27 and the second through-holes 28 of the first FPC 21 and the second FPC 22, the present invention is not limited to this. For example, a configuration is possible in which the first FPC or the second FPC is provided with protruding portions that are to be inserted into recessed portions of the protector. As another example, end portions of the first FPC and the second FPC may be fixed to the protector by a fixing means (tape winding or the like).

(5) The wiring module 20, 120 may include a FPC (e.g., a third FPC) other than the first FPC 21, 121 and the second FPC 22, 122.

(6) Although the first FPC 21, 121 and the second FPC 22, 122 include the first extension portion 26A, 126A and the second extension portion 26B, 126B, the present invention is not limited to this. For example, the first FPC and the second FPC may be formed so as to entirely extend with the same width dimension as the base portion.

### LIST OF REFERENCE NUMERALS

1 Vehicle

2 Power storage pack

3 PCU

4 Wire harness

10, 110 Power storage module

11 Power storage element

12A, 12B Electrode terminal

20, 120 Wiring module

21, 121 First FPC (first flexible printed circuit)

22, 122 Second FPC (second flexible printed circuit)

23, 123 FPC body

24, 124 Base portion

24A Mounting surface

25 Slit portion

26A, 126A First extension portion

26B, 126B Second extension portion

27 First through-hole

28 Second through-hole

29 Fixing portion

30 Connector

31 Housing

32 Connector terminal

33 Reinforcing plate

33A Passage hole

35 Bus bar

36 Connection piece

40 Protector

41 Protector body

42A First region

42B Second region

42C Ventilation region

43 Protruding portion

43A Locking portion

44 Ventilation hole

45 Mounting recessed portion

46 Bus bar arrangement portion

47 Passage hole

48 Restricting claw

49 Insulating wall

1. A wiring module comprising:
a first flexible printed circuit; and
a second flexible printed circuit provided separately from the first flexible printed circuit,
wherein the first flexible printed circuit and the second flexible printed circuit are arranged so as to be continuous in a first direction and are shaped as a band that extends in the first direction,
a connector is mounted to each of the first flexible printed circuit and the second flexible printed circuit, and
a fitting direction in which the connector mounted to the first flexible printed circuit is fitted to a partner connector is different from a fitting direction in which the connector mounted to the second flexible printed circuit is fitted to a partner connector.

2. The wiring module according to claim 1,
wherein the connector mounted to the first flexible printed circuit is mounted to an end portion of the first flexible printed circuit on a side opposite to the second flexible printed circuit.

3. The wiring module according to claim 2,
wherein the connector mounted to the second flexible printed circuit is mounted to an end portion of the second flexible printed circuit on a side opposite to the first flexible printed circuit.

4. The wiring module according to any one of claims 1 to 3,
wherein the connectors are arranged inward of the first flexible printed circuit and the second flexible printed circuit in the first direction.

5. The wiring module according to any one of claims 1 to 4,
wherein the connectors are arranged inward of the first flexible printed circuit and the second flexible printed circuit in a second direction that is orthogonal to the first direction.

6. The wiring module according to any one of claims 1 to 5,
wherein the connectors are open in the first direction.

7. The wiring module according to any one of claims 1 to 6,
wherein at least one of the first flexible printed circuit and the second flexible printed circuit includes a first extension portion that extends in a band shape and a second extension portion that extends in band shape along the first extension portion while being separated from the first extension portion by a gap.

8. The wiring module according to any one of claims 1 to 7, further comprising:
an insulating protector having a first region on which the first flexible printed circuit is arranged and a second region on which the second flexible printed circuit is arranged,
wherein the first flexible printed circuit and the second flexible printed circuit each include a fixing portion that is fixed to the protector.

9. The wiring module according to claim 8,
wherein the first flexible printed circuit and the second flexible printed circuit each include a mounting surface on which the connector is mounted, and
the protector includes a mounting recessed portion that is recessed in a direction opposite to the connectors in a region corresponding to the mounting surface of at least one of the first flexible printed circuit and the second flexible printed circuit.

10. The wiring module according to claim 9,
wherein the protector includes a mounting recessed portion that is recessed in a direction opposite to the connectors in regions corresponding to the mounting surfaces of both the first flexible printed circuit and the second flexible printed circuit.

11. The wiring module according to any one of claims 1 to 10,
wherein the wiring module is a vehicular wiring module that is to be mounted and used in a vehicle.
